(19) United States
(12) Patent Application Publication
(10) Pub. No.: US 2026/0164798 A1
(43) Pub. Date: Jun. 11, 2026

(54) DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Yajuan LI, Wuhan, Hubei (CN); Cheng WANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/706,363

(22) PCT Filed: Mar. 11, 2024
(86) PCT No.: PCT/CN2024/080933

§ 371 Date: Apr. 30, 2024

(30) Foreign Application Priority Data
Feb. 8, 2024 (CN) 202410179094.7

(51) Int. Cl. H10D 86/40; G09G 3/32; H10D 86/60

(52) U.S. Cl. CPC H10D 86/441; G09G 3/32; H10D 86/60; G09G 2300/0408; G09G 2300/0426; G09G 2300/043; G09G 2300/0819; G09G 2310/0267; G09G 2320/0233

(57) ABSTRACT

The present application disclosed a display panel, in which a second connection terminal of a first input signal line is electrically connected to one bonding terminal, and a part of the first input signal line is located in a fan-out wiring area; a fourth connection terminal of a second input signal line is electrically connected to one bonding terminal, and a part of the second input signal line is located in the fan-out wiring area; a voltage applied by the bonding terminal electrically connected to the first input signal line is the same as a voltage applied by the bonding terminal electrically connected to the second input signal line.

### TECHNICAL FIELD

The present application relates to the field of display technologies, and in particular to a display panel.

### BACKGROUND

In the display panel, a gate driver on array (GOA) solution generates a scanning signal through a GOA circuit, and transmits the scanning signal to an in-plane pixel driving circuit to realize light emission of the in-plane pixel.

The GOA circuit performs scanning row by row to transmit the scanning signal to the pixel driving circuit of the corresponding row. For example, a plurality of rows of GOA units in the GOA circuit each input a high-potential signal through a high-potential scanning signal line. When the pixel driving circuit of the row uses the high-potential signal for charging, and the pixel driving circuit of the other rows also use their high-potential scanning signals for charging, the load of the high-potential scanning signal line becomes larger, so that the potential in the high-potential scanning signal line becomes smaller, thereby affecting signal stability in the pixel driving circuit, and causing display unevenness in the display panel.

### SUMMARY OF THE INVENTION

One or more embodiments of the present application provides a display panel that can improve transmission stability of signals in a first input signal line and a second input signal line, and improve display uniformity of the display panel.

One or more embodiments of the present application provides a display panel including a display area, a first driving circuit area located on a first side of the display area, and a fan-out wiring area located on a second side of the display area;
the display panel further includes:
a panel body including first gate driving circuits disposed in the first driving circuit area, one or more bonding terminals disposed at a side of the fan-out wiring area away from the display area, a first input signal line, and a second input signal line;
the first input signal line includes a first connection terminal and an opposing second connection terminal, the first connection terminal is electrically connected to one or more of the first gate driving circuits, the second connection terminal is electrically connected to one of the one or more bonding terminals, and a part of the first input signal line is located in the fan-out wiring area;
the second input signal line includes a third connection terminal and an opposing fourth connection terminal, the third connection terminal is electrically connected to one or more of the first gate driving circuits, the fourth connection terminal is electrically connected to one of the one or more bonding terminals, and a part of the second input signal line is located in the fan-out wiring area;
wherein a voltage applied by the bonding terminal electrically connected to the first input signal line is the same as a voltage applied by the bonding terminal electrically connected to the second input signal line.

### DESCRIPTION OF THE DRAWINGS

FIG. 1 is a schematic diagram showing the distribution of the display panel according to the related art;

FIG. 2 shows a waveform of the output voltage signal of the gate driving circuit according to the related art;

FIG. 3 shows a brightness curve for different rows of the display panel according to the related art;

FIG. 4 is a schematic diagram of a planar distribution of the display panel according to embodiments of the present application;

FIG. 5 is a schematic diagram of a wire connection of the display panel according to embodiments of the present application;

FIG. 6 is a schematic diagram of a structure of the first signal input line and the second signal input line according to embodiments of the present application;

FIG. 7 is a schematic diagram of a structure of the pixel driving circuit according to embodiments of the present application;

FIGS. 8 and 9 are schematic diagram of structures of the first gate control circuit according to embodiments of the present application;

FIGS. 10 and 11 show the waveforms of output signals of a first gate control circuit according to embodiments of the present application;

FIG. 12 is a schematic diagram of another wire connection of the display panel according to embodiments of the present application;

FIG. 13 is a schematic diagram of another structure of the first signal input line and the second signal input line according to embodiments of the present application;

FIG. 14 is a schematic diagram of another wire connection of the display panel according to embodiments of the present application;

FIG. 15 is a schematic diagram of another structure of the first signal input line and the second signal input line according to embodiments of the present application;

FIG. 16 is a schematic diagram of another wire connection of the display panel according to embodiments of the present application;

FIG. 17 is a schematic diagram of another structure of the first signal input line and the second signal input line according to embodiments of the present application;

FIG. 18 is a schematic diagram of another wire connection of the display panel according to embodiments of the present application;

FIG. 19 is a schematic diagram of another structure of the first signal input line and the second signal input line according to embodiments of the present application;

FIG. 20 is a schematic diagram of another wire connection of the display panel according to embodiments of the present application;

FIG. 21 is a schematic diagram of another structure of the first signal input line and the second signal input line according to embodiments of the present application.

### EMBODIMENTS OF THE INVENTION

The technical solution in the embodiments of the present invention will be clearly and completely described with reference to the accompanying drawings in the embodiments in the present application. It will be apparent that the described embodiments are only part of the embodiments of the present application, and not all embodiments. Based on the embodiments in the present application, all other embodiments obtained by a person skilled in the art without involving any inventive effort are within the scope of the present application.

The following disclosure provides many different embodiments or examples for implementing the different structures of the present application. In order to simplify the disclosure of the present application, components and arrangements of specific examples are described below. Of course, they are merely examples and are not intend to limit the application. In addition, the present application may repeat reference numerals and/or reference letters in various examples, such repetition being for the purpose of simplicity and clarity, without itself indicating a relationship between the various embodiments and/or arrangements discussed. In addition, the present application provides examples of various specific processes and materials, but one of ordinary skill in the art will recognize the application of other processes and/or the use of other materials.

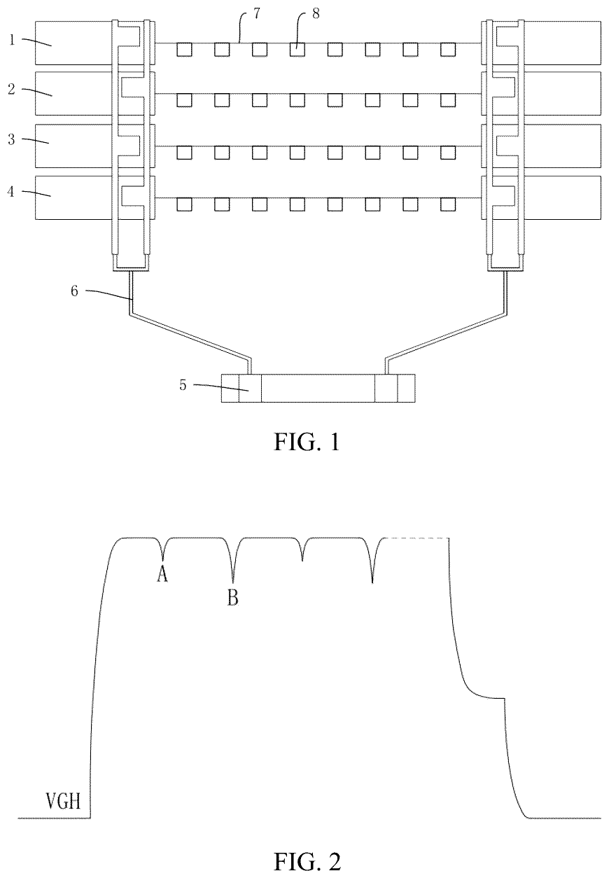

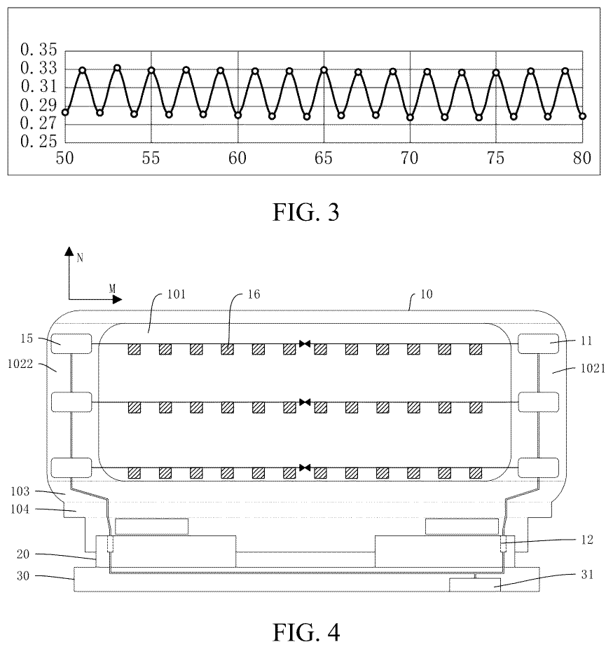

Referring to FIG. 1, FIG. 2, and FIG. 3, in the related art, the display panel includes a plurality of row gate control circuits, for example, the first row gate control circuit 1, the second row gate control circuit 2, the third row gate control circuit 3, and the fourth row gate control circuit 4. The signal input terminal 5 transmits the scanning signals to the plurality of row gate control circuits through the transmission signal line 6, and the row gate control circuit transmits the voltage to the pixel circuit 8 in the display area through the output signal line 7. The first row gate control circuit 1 and the third row gate control circuit 3 are directly connected and connected to the transmission signal line 6, and the second row gate control circuit 2 and the fourth row gate control circuit 4 are directly connected and connected to the transmission signal line 6. In the driving process of the display panel, the plurality of row gate control circuits perform scanning row by row. When the second row gate control circuit 2 and the fourth row gate control circuit 4 charge the pixel circuit 8, the load of the transmission signal line 6 is increased, and the voltage in the transmission signal line 6 is reduced, so that the voltage transmitted to the first row gate control circuit 1 is reduced, and the sharp angle A as shown in FIG. 2 occurs. When the third row gate control circuit 3 charges the pixel circuit 8, the load of the transmission signal line 6 is increased, and the voltage in the transmission signal line 6 is reduced, so that the voltage transmitted to the first row gate control circuit 1 is reduced, and the sharp angle B as shown in FIG. 2 occurs. Since the third row gate control circuit 3 is directly connected to the first row gate control circuit 1, the third row gate control circuit 3 has the great influence on the voltage in the first row gate control circuit 1 when charging. Therefore, the reduction degree at the sharp angle B is greater than the reduction degree at the sharp angle A. Since the potentials in the other row gate control circuits are also affected by the first row gate control circuit 1 as described above, the brightness of the different rows in the display panel fluctuates as shown in FIG. 3, and the display with a fine row mura effect of the display panel is uneven.

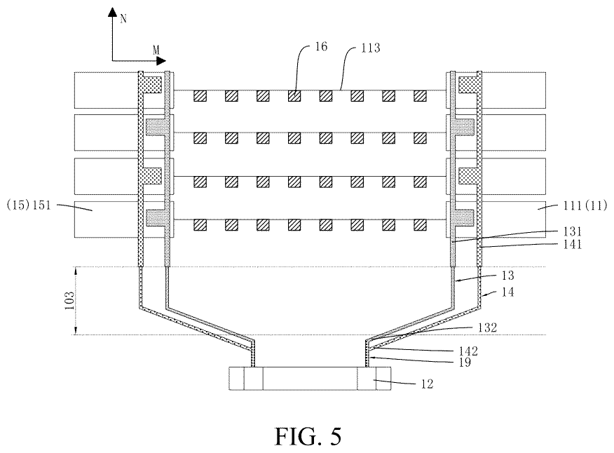

Referring to FIGS. 4 and 5, embodiments of the present application provides the display panel including the display area 101, the first driving circuit area 1021 located on the first side of the display area 101, and the fan-out wiring area 103 located on the second side of the display area 101; the display panel further includes the panel body 10; the panel body 10 includes the first gate driving circuits 11 disposed in the first driving circuit area 1021, at least one bonding terminal 12 disposed at the side of the fan-out wiring area 103 away from the display area 101, the first input signal line 13, and the second input signal line 14.

The first input signal line 13 includes the first connection terminal 131 and the opposing second connection terminal 132, the first connection terminal 131 is electrically connected to the first gate driving circuits 11, the second connection terminal 132 is electrically connected to one of the bonding terminals 12, and a part of the first input signal line 13 is located in the fan-out wiring area 103.

The second input signal line 14 includes the third connection terminal 141 and the opposing fourth connection terminal 142, the third connection terminal 141 is electrically connected to the first gate driving circuits 11, the fourth connection terminal 142 is electrically connected to one of the bonding terminals 12, and a part of the second input signal line 14 is located in the fan-out wiring area 103.

Further, a voltage applied by the bonding terminal 12 electrically connected to the first input signal line 13 is the same as a voltage applied by the bonding terminal 12 electrically connected to the second input signal line 14.

In the practice use of the embodiments of the present invention, the connection points of the first input signal line 13 and the second input signal line 14 are disposed at the fan-out wiring area 103 or a side further away from the first gate driving circuits 11, so that the connection points of the first input signal line 13 and the first gate driving circuits 11 are further distant from the connection points of the second input signal line 14 and the first gate driving circuits 11. The mutual influence between signal transmission in the first input signal line 13 and signal transmission in the second input signal line 14 is reduced, the transmission stability of signals in the first input signal line 13 and the second input signal line 14 can be improved, and the display uniformity of the display panel can be improved.

In one or more embodiments of the present application, the first input signal line and the second input signal line are electrically connected to the same one of the bonding terminals.

In one or more embodiments of the present application, the panel body further includes the switching signal line, one terminal of the switching signal line being connected to the bonding terminal, and the other terminal of the switching signal line being connected to the second connection terminal and the fourth connection terminal.

In one or more embodiments of the present application, both the second connection terminal and the fourth connection terminal are located in the fan-out wiring area.

In one or more embodiments of the present application, the display panel further includes the bending area disposed on the side of the fan-out wiring area away from the display area, and the second connection terminal, the fourth connection terminal, and a part of the switching signal line are all located in the bending area.

In one or more embodiments of the present application, the display panel further includes the bending area disposed on the side of the fan-out wiring area away from the display area, and the second connection terminal, the fourth connection terminal, and the switching signal line are all disposed on the side of the bending area away from the fan-out wiring area.

In one or more embodiments of the present application, the switching signal line extends in the first direction, the first direction being the direction in which the bending area is close to the fan-out wiring area.

In one or more embodiments of the present application, the first input signal line extends in the direction oblique to the first direction in the fan-out wiring area, the first input signal line extends in the first direction in the bending area, and the first input signal line extends in the direction oblique to the first direction between the bending area and the switching signal line;
the second input signal line extends in the direction inclined to the first direction in the fan-out wiring area, the second input signal line extends in the first direction in the bending area, and the second input signal line extends in the direction inclined to the first direction between the bending area and the switching signal line.

In one or more embodiments of the present application, the panel body includes the source-drain layer and the gate layer;
the source-drain layer includes the switching signal line having a length in the first direction of greater than or equal to 100 microns;
or, the gate layer includes the switching signal line having a length in the first direction of greater than or equal to 20 microns.

In one or more embodiments of the present application, the first input signal line includes a plurality of first line segments, and the plurality of first line segments are each independently located at the source-drain layer or the gate layer, the second input signal line includes a plurality of second line segments, and the plurality of second line segments are each independently located at the source-drain layer or the gate layer.

In one or more embodiments of the present application, the bonding terminal electrically connected to the first input signal line and the bonding terminal electrically connected to the second input signal line are different bonding terminals.

In one or more embodiments of the present application, the panel body includes a plurality of pixel driving circuits disposed in the display area and arranged in a second direction and a third direction, the second direction intersects the third direction, and the first gate driving circuit is one of a plurality of first gate control circuits disposed in the first driving circuit area and arranged in the third direction;
the panel body further includes a plurality of first output signal lines, one terminal of each of the first output signal lines being connected to one of the first gate control circuits, the other terminal of each of the first output signal lines being connected to a plurality of pixel driving circuits arranged in the second direction, the first output signal lines being used to transmit voltage signals in the first input signal line and the second input signal line to the pixel driving circuits.

In one or more embodiments of the present application, the first input signal line is connected to a plurality of first gate control circuits arranged in the third direction, the second input signal line is connected to a plurality of first gate control circuits arranged in the third direction, and the plurality of first gate control circuits connected to the first input signal line alternates with the plurality of first gate control circuits connected to the second input signal line in the third direction.

In one or more embodiments of the present application, the first gate driving circuits further include a plurality of second gate control circuits disposed in the first driving circuit area and arranged in the third direction, the panel body further includes a plurality of second output signal lines, and the plurality of second gate control circuits are located on one side of the plurality of first gate control circuits away from or close to the display area;
one terminal of each of the second output signal lines is connected to one of the second gate control circuits, and the other terminal of each of the second output signal lines is connected to the plurality of pixel driving circuits arranged in the second direction.

In one or more embodiments of the present application, the panel body further includes a first sub-line and a second sub-line connected to the first connection terminal, the first sub-line is connected to a plurality of first gate control circuits arranged in the third direction, the second sub-line is connected to a plurality of first gate control circuits arranged in the third direction, and the plurality of first gate control circuits connected to the first sub-line alternate with the plurality of first gate control circuits connected to the second sub-line in the third direction;
the panel body further includes a third sub-line and a fourth sub-line connected to the third connection terminal, the third sub-line is connected to a plurality of second gate control circuits arranged in the third direction, the fourth sub-line is connected to a plurality of second gate control circuits arranged in the third direction, and the plurality of second gate control circuits connected to the third sub-line alternate with the plurality of second gate control circuits connected to the fourth sub-line in the third direction.

In one or more embodiments of the present application, the first input signal line is connected to a plurality of first gate control circuits arranged in the third direction, the second input signal line is connected to a plurality of first gate control circuits arranged in the third direction, and the first gate control circuits connected to the first input signal line alternate with the first gate control circuits connected to the second input signal line are alternately arranged in the third direction;
the panel body further includes a third input signal line, a fifth connection terminal of the third input signal line is electrically connected to the second gate control circuits, a sixth connection terminal of the third input signal line passes through at least a part of the fan-out wiring area and is electrically connected to one of the bonding terminals, and a voltage applied by the one of the bonding terminals electrically connected to the first input signal line is the same as a voltage applied by the one of the bonding terminals electrically connected to the third input signal line.

In one or more embodiments of the present application, the panel body further includes a fourth input signal line, a seventh connection terminal of the fourth input signal line is electrically connected to the second gate control circuits, an eighth connection terminal of the fourth input signal line passes through at least a part of the fan-out wiring area and is electrically connected to one of the bonding terminals, and a voltage applied by the one of the bonding terminals electrically connected to the first input signal line is the same as a voltage applied by the one of the bonding terminals electrically connected to the fourth input signal line;
the third input signal line is connected to a plurality of second gate control circuits arranged in the third direction, the fourth input signal line is connected to a plurality of second gate control circuits arranged in the third direction, and the plurality of the second gate control circuits connected to the third input signal line alternate with the plurality of the second gate control circuits connected to the fourth input signal line in the third direction.

In one or more embodiments of the present application, the panel body further includes a fifth sub-line and a sixth sub-line connected to the fifth connection terminal, the fifth sub-line is connected to a plurality of second gate control circuits arranged in the third direction, the sixth sub-line is connected to a plurality of second gate control circuits arranged in the third direction, and the plurality of second gate control circuits connected to the fifth sub-line alternate with the plurality of second gate control circuits connected to the sixth sub-line in the third direction.

In one or more embodiments of the present application, each of the pixel driving circuits includes a driving transistor and a compensation transistor, a first electrode of the driving transistor and a first electrode of the compensation transistor are both connected to a first node, a gate of the driving transistor and a second electrode of the compensation transistor are both connected to a second node, and the first output signal line is connected to a gate of the compensation transistor.

In one or more embodiments of the present application, the compensation transistor is an N-type thin film transistor, and a voltage applied by the one of the bonding terminals electrically connected to the first input signal line and a voltage applied by the one of the bonding terminals electrically connected to the second input signal line are both high potentials.

Specifically, with reference to FIGS. 4 and 5, the display panel provided in the present embodiment includes the display area 101 and the non-display area adjacent to the display area 101, and the non-display area includes the first driving circuit area 1021 located on the first side of the display area 101, the fan-out wiring area 103 located on the second side of the display area 101, and the second driving circuit area 1022 located on the third side of the display area 101. The first side and the third side are opposite sides of the display area 101, and the second side is located between the first side and the third side.

The display panel further includes the panel body 10, the flexible circuit board 20, and the circuit board 30, one end of the flexible circuit board 20 is connected to one side of the panel body 10 away from the fan-out wiring area 103, and the other end of the flexible circuit board 20 is connected to the circuit board 30. The circuit board 30 transmits the signals to the panel body 10 through the flexible circuit board 20 to realize the display function of the display panel.

In one or more embodiments, the driver chip 31 is provided on the circuit board 30 to provide the display signals for the panel body 10.

Further, the panel body 10 includes the first gate driving circuits 11 disposed in the first driving circuit area 1021, the second gate driving circuits 15 disposed in the second driving circuit area 1022, and a plurality of pixel driving circuits 16 disposed in the display area 101. A plurality of pixel driving circuits 16 are arranged in an array arrangement along the second direction M and the third direction N, where the second direction M and the third direction N intersect.

In one or more embodiments, the second direction M and the third direction N are perpendicular, and the third direction N is the direction in which the fan-out wiring area 103 is close to the display area 101. It will be appreciated that in other embodiments of the present application, the third direction N may also be other directions, and is not limited herein.

One of the first gate driving circuits 11 and one of the second gate driving circuits 15 jointly drive a plurality of pixel driving circuits 16 arranged in the second direction M.

The panel body 10 further includes at least one bonding terminal 12 disposed on the side of the fan-out wiring area 103 away from the display area 101, and the flexible circuit board 20 is bound to the bonding terminal(s) 12, so that the circuit board 30 can transmit the signals to the first gate driving circuits 11 and the second gate driving circuits 15 through the flexible circuit board 20 to perform scanning on the plurality of pixel driving circuits 16 row by row.

It should be noted that in the embodiments of the present application, the first gate driving circuits 11 and the second gate driving circuits 15 are symmetrically arranged with respect to the display area 101, and the connection and signal transmission between the first gate driving circuits 11 and the flexible circuit board 20 and the circuit board 30 are the same as the connection and signal transmission between the second gate driving circuits 15 and the flexible circuit board 20 and the circuit board 30. Therefore, in the embodiments of the present application, the connection and signal transmission between the first gate driving circuits 11 and the flexible circuit board 20 and the circuit board 30 are described as an example, and through a symmetrical transform with respect to the display area 101, the connection structure between the second gate driving circuits 15 and the flexible circuit board 20 and the circuit board 30 will be obtained, and the same applies to the signal transmission.

The panel body 10 includes the first input signal line 13 and the second input signal line 14. The first input signal line 13 includes the first connection terminal 131 and the opposing second connection terminal 132. The first connection terminal 131 is electrically connected to the first gate driving circuits 11. The second connection terminal 132 passes through at least part of the fan-out wiring area 103 and is electrically connected to one of the bonding terminal(s) 12. The second input signal line 14 includes opposing third and fourth connection terminals 141 and 142. The third connection terminal 141 is electrically connected to the first gate driving circuits 11, and the fourth connection terminal 142 passing through at least part of the fan-out wiring area 103 and electrically connected to one of the bonding terminal(s) 12.

Further, the voltage applied by the bonding terminal 12 electrically connected to the first input signal line 13 is the same as the voltage applied by the bonding terminal 12 electrically connected to the second input signal line 14. According to the embodiments of the present application, the connection points of the first input signal line 13 and the second input signal line 14 are disposed at the fan-out wiring area 103 or a side further away from the first gate driving circuits 11, so that the connection points of the first input signal line 13 and the first gate driving circuits 11 are further distant from the connection points of the second input signal line 14 and the first gate driving circuits 11, the mutual influence between the signal transmission in the first input signal line 13 and the signal transmission in the second input signal line 14 is reduced, the transmission stability of the signals in the first input signal line 13 and the second input signal line 14 can be improved, and the display uniformity of the display panel can be improved.

In one or more embodiments, the first input signal line 13 and the second input signal line 14 are electrically connected to one same bonding terminal 12, and the panel body 10 further includes the switching signal line 19, one terminal of which is connected to the bonding terminal 12, and the other terminal of which is connected to the second connection terminal 132 and the fourth connection terminal 142.

Further, the display panel further includes the bending area 104 provided on the side of the fan-out wiring area 103 away from the display area 101.

In one or more embodiments, the second connection terminal 132, the fourth connection terminal 142, and a part of the switching signal line 19 are all located in the fan-out wiring area 103. The switching signal line 19 is connected to the second connection terminal 132 and the fourth connection terminal 142 in the fan-out wiring area 103.

In one or more embodiments, the display panel further includes the bending area 104 disposed on the side of the fan-out wiring area 103 away from the display area 101. The second connection terminal 132, the fourth connection terminal 142, and a part of the switching signal line 19 are all located in the bending area 104. The switching signal line 19 is connected to the second connection terminal 132 and the fourth connection terminal 142 in the bending area 104.

In one or more embodiments, the second connection terminal 132, the fourth connection terminal 142, and the switching signal line 19 are all located on the side of the bending area 104 away from the fan-out wiring area 103. The switching signal line 19 is connected to the second connection terminal 132 and the fourth connection terminal 142 on the side of the bending area 104 away from the fan-out wiring area 103.

Furthermore, in other embodiments of the present application, the first input signal line 13 and the second input signal line 14 may also be connected to different bonding terminals 12.

The more distant the connection points of the first input signal line 13 and the second input signal line 14 are arranged away from the first gate driving circuits 11, the smaller the mutual influence between the signal transmission in the first input signal line 13 and the signal transmission in the second input signal line 14. Therefore, embodiments in which the switching signal line 19 is connected to the second connection terminal 132 and the fourth connection terminal 142 at the side of the bending area 104 away from the fan-out wiring area 103 is described as an example.

The connection of the first input signal line 13 and the second input signal line 14 in the embodiments of the present application will be described in detail below with reference to specific embodiments.

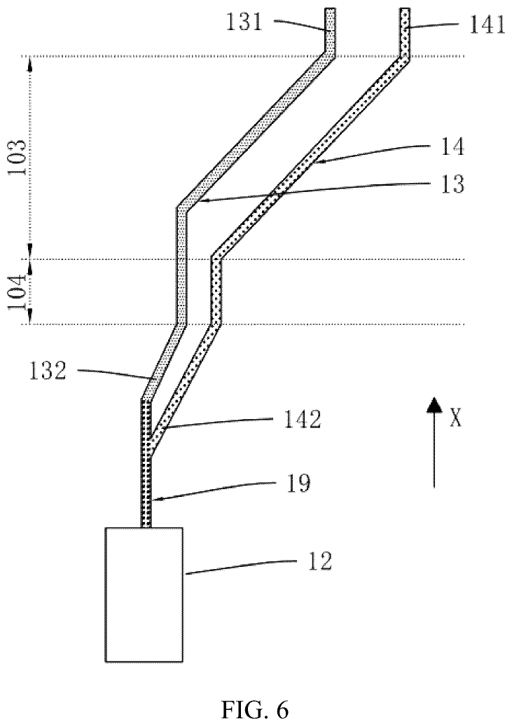

In one or more embodiments of the present application, please continue referring to FIGS. 4, 5 and 6, in which the first input signal line 13 and the second input signal line 14 are connected to the same bonding terminal 12.

The first gate driving circuits 11 include a plurality of first gate control circuits 111 arranged in the third direction N, the second gate driving circuits 15 include a plurality of third gate control circuits 151 arranged in the third direction N. Each of the first gate control circuits 111 and a corresponding one of the third gate control circuits 151 jointly transmit signals to a plurality of pixel driving circuits 16 arranged in the first direction X. It should be noted that since the connection between the first gate control circuits 111 and the bonding terminal 12 is the same as the connection between the third gate control circuits 151 and the bonding terminal 12, and is symmetrically provided with respect to the display area 101, only the connection between the first gate control circuits 111 and the bonding terminal 12 will be described in the present embodiment.

In one or more embodiments, the panel body 10 further includes a plurality of first output signal lines 113, one terminal of each of which is connected to one of the first gate control circuits 111, and the other terminal of each of which is connected to a plurality of pixel driving circuits 16 arranged in the second direction M. The first output signal lines 113 are used for transmitting voltage signals in the first input signal line 13 and the second input signal line 14 to the pixel driving circuits 16.

In the embodiments of the present application, the driver chip 31 on the circuit board 30 transmits the signals to the flexible circuit board 20, which transmits the signals to the first input signal line 13 and the second input signal line 14 through the bound bonding terminal 12. And the first input signal line 13 and the second input signal line 14 transmit the signals to the first gate control circuits 111, and then transmits the signals to the pixel driving circuits 16 through the first output signal lines 113 to scan and drive each pixel driving circuit 16.

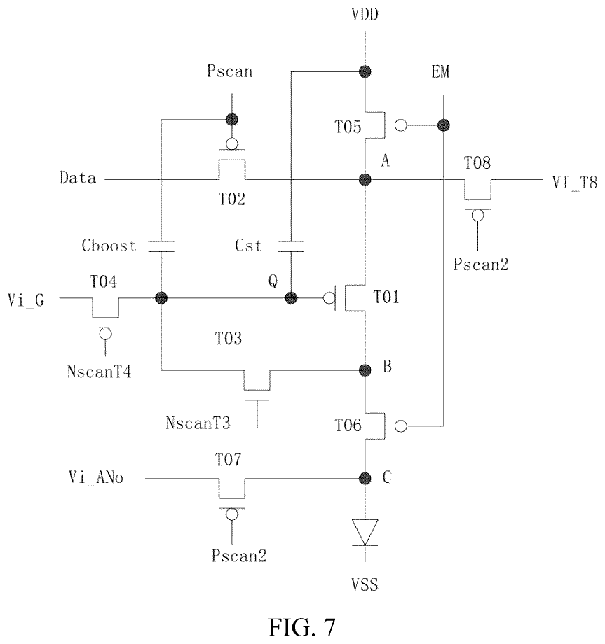

In one or more embodiments, as shown in FIG. 7, the pixel driving circuits 16 each include the light emitting device, the driving transistor T01, the switching transistor T02, the compensation transistor T03, the first reset transistor T04, the first light emitting control transistor T05, the second light emitting control transistor T06, the second reset transistor T07, the third reset transistor T08, the first capacitor Cst, and the second capacitor Cboost.

The first electrode of the driving transistor T01 is connected to the first node B. The gate of the driving transistor T01 is connected to the second node Q. And the second electrode of the driving transistor T01 is connected to the third node A.

The first electrode of the first switching transistor T02 is connected to the data signal Data. The gate of the first switching transistor T02 is connected to the first scanning signal Pscan, and the second electrode of the first switching transistor T02 is connected to the third node A.

The first electrode of the compensation transistor T03 is connected to the first node B, the gate of the compensation transistor T03 is connected to the second scanning signal NscanT3, and the second electrode of the compensation transistor T03 is connected to the second node Q.

The first electrode of the first reset transistor T04 is connected to the first reset signal Vi_G, the gate of the first reset transistor T04 is connected to the third scanning signal NscanT4, and the second electrode of the first reset transistor T04 is connected to the second node Q.

The first electrode of the first light-emitting control transistor T05 is connected to the first power supply signal VDD, the gate of the first light-emitting control transistor T05 is connected to the light-emitting control signal EM, and the second electrode of the first light-emitting control transistor T05 is connected to the third node A.

The first electrode of the second light-emitting control transistor T06 is connected to the first node B, the gate of the second light-emitting control transistor T06 is connected to the light-emitting control signal EM, and the second electrode of the second light-emitting control transistor T06 is connected to the fourth node C.

The first electrode of the second reset transistor T07 is connected to the second reset signal Vi_ANo, the gate of the second reset transistor T07 is connected to the fourth scanning signal PScan2, and the second electrode of the second reset transistor T07 is connected to the fourth node C.

The first electrode of the third reset transistor T08 is connected to the third reset signal Vi_T8, the gate of the third reset transistor T08 is connected to the fourth scanning signal PScan2, and the second electrode of the third reset transistor T08 is connected to the third node A.

The first electrode of the light emitting device is connected to the fourth node C, and the second electrode of the light emitting device is connected to the second power supply signal VSS.

The first capacitor Cst is connected between the second node Q and the third node A, and the second capacitor Cboost is connected between the second node Q and the first scanning signal PScan.

Further, referring to FIGS. 5 and 7, in the present embodiment, the first output signal line 113 is connected to the gate of the compensation transistor T03, that is, the output signal of the first output signal line 113 is the second scanning signal NscanT3. In one or more embodiments, the compensation transistor T03 is an N-type thin film transistor, and the voltage applied by the bonding terminal 12 electrically connected to the first input signal line 13 and the voltage applied by the bonding terminal 12 electrically connected to the second input signal line 14 are both high potentials.

It will be appreciated that the compensation transistor T03 is connected to the first electrode and the gate of the driving transistor T01. Therefore, if the signals transmitted in the first input signal line 13 and the second input signal line 14 are unstable, the voltage applied to the gate of the compensation transistor T03 is also unstable, and the parasitic capacitance exists between the gate of the compensation transistor T03 and the gate of the driving transistor T01. Therefore, the voltage fluctuation on the gate of the compensation transistor T03 causes a fluctuate on the gate of the driving transistor T01, thereby affecting the stability of the signal transmission in the driving transistor T01, causing the electrical signals transmitted to the light emitting device to be unstable, and causing the display panel to have an unevenly display with the fine row mura effect.

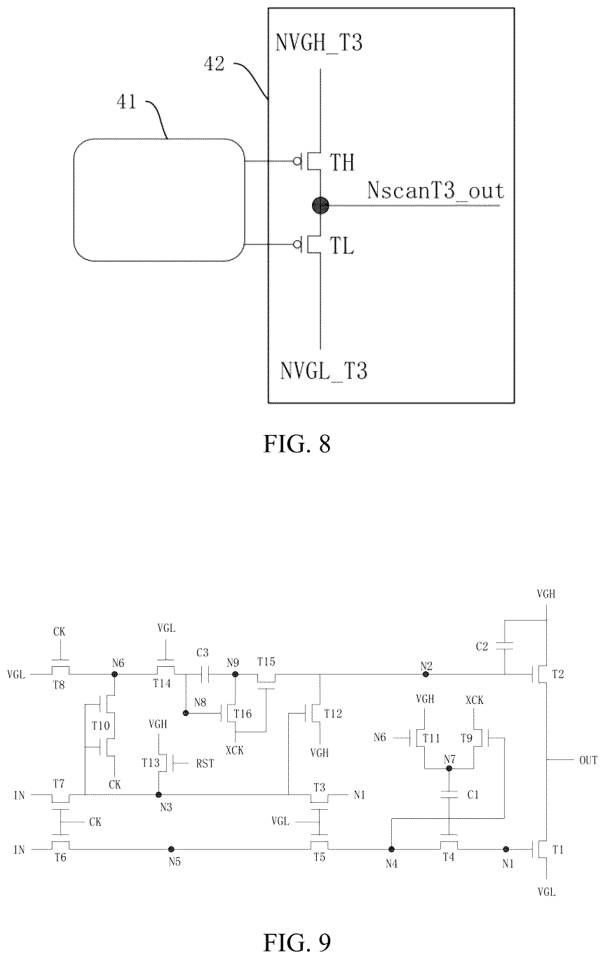

Further, as shown in FIG. 8, the first gate control circuits 111 provided in the present application each include the signal control unit 41 and the signal generation unit 42. The signal generation unit 42 may connect the high potential signal NVGH_T3 and the low potential signal NVGL_T3, and output the high potential signal NVGH_T3 to the signal output terminal NscanT3_out under the control of the high potential transistor TH, or output the high potential signal NVGL_T3 to the signal output terminal NscanT3_out under the control of the low potential transistor TL, and the signal output terminal NscanT3_out may be connected to the gate of the compensation transistor T03 through the first output signal line 113. The signal control unit 41 is connected to the gate of the high-potential transistor TH and the gate of the low-potential transistor TL to turn on the high-potential transistor TH or the low-potential transistor TL according to the control of the various clock signals.

In one or more embodiments, as shown in FIG. 9, one or more embodiments of the present application provides each first gate control circuit 111 of an 16T3C architecture, where the first gate control circuit 111 includes the first transistor T1, the second transistor T2, the third transistor T3, the fourth transistor T4, the fifth transistor T5, the sixth transistor T6, the seventh transistor T7, the eighth transistor T8, the ninth transistor T9, the tenth transistor T10, an eleventh transistor T11, the twelfth transistor T12, the thirteenth transistor T13, the fourteenth transistor T14, the fifteenth transistor T15, the sixteenth transistor T16, the first capacitor C1, the second capacitor C2, and the third capacitor C3.

The first electrode of the first transistor T1 is connected to the low potential signal VGL, the gate of the first transistor T1 is connected to the first node N1, and the second electrode of the first transistor T1 is connected to the signal output terminal OUT.

The first electrode of the second transistor T2 is connected to the high-potential signal VGH, the gate of the second transistor T2 is connected to the second node N2, and the second electrode of the second transistor T2 is connected to the signal output terminal OUT.

The first electrode of the third transistor T3 is connected to the first node N1, the gate of the third transistor T3 is connected to the low potential signal VGL, and the second electrode of the third transistor T3 is connected to the third node N3.

The first electrode of the fourth transistor T4 is connected to the first node N1, the gate of the fourth transistor T4 is connected to the first capacitor C1, and the second electrode of the fourth transistor T4 is connected to the fourth node N4.

The first electrode of the fifth transistor T5 is connected to the fourth node N4, the gate of the fifth transistor T5 is connected to the low potential signal VGL, and the second electrode of the fifth transistor T5 is connected to the fifth node N5.

The first electrode of the sixth transistor T6 is connected to the control signal IN, the gate of the sixth transistor T6 is connected to the first clock signal CK, and the second electrode of the sixth transistor T6 is connected to the fifth node N5.

The first electrode of the seventh transistor T7 is connected to the control signal IN, the gate of the seventh transistor T7 is connected to the first clock signal CK, and the second electrode of the seventh transistor T7 is connected to the third node N3.

The first electrode of the eighth transistor T8 is connected to the low potential signal VGL, the gate of the eighth transistor T8 is connected to the first clock signal CK, and the second electrode of the eighth transistor T8 is connected to the sixth node N6.

The first electrode of the ninth transistor T9 is connected to the second clock signal XCK, the gate of the ninth transistor T9 is connected to the fourth node N4, and the second electrode of the ninth transistor T9 is connected to the seventh node N7.

The first electrode of the tenth transistor T10 is connected to the first clock signal CK, the gate of the tenth transistor T10 is connected to the third node N3, and the second electrode of the tenth transistor T10 is connected to the sixth node N6. The tenth transistor T10 may be double gate transistor.

The first electrode of the eleventh transistor T11 is connected to the high potential signal VGH, the gate of the eleventh transistor T11 is connected to the sixth node N6, and the second electrode of the eleventh transistor T11 is connected to the seventh node N7.

The first electrode of the twelfth transistor T12 is connected to the high potential signal VGH, the gate of the twelfth transistor T12 is connected to the third node N3, and the second electrode of the twelfth transistor T12 is connected to the second node N2.

The first electrode of the thirteenth transistor T13 is connected to the high potential signal VGH, the gate of the thirteenth transistor T13 is connected to the control signal RST, and the second electrode of the thirteenth transistor T13 is connected to the third node N3.

The first electrode of the fourteenth transistor T14 is connected to the sixth node N6, the gate of the fourteenth transistor T14 is connected to the low potential signal VGL, and the second electrode of the fourteenth transistor T14 is connected to the eighth node N8.

The first electrode of the fifteenth transistor T15 is connected to the ninth node N9, the gate of the fifteenth transistor T15 is connected to the second clock signal XCK, and the second electrode of the fifteenth transistor T15 is connected to the second node N2.

The first electrode of the sixteenth transistor T16 is connected to the second clock signal XCK, the gate of the sixteenth transistor T16 is connected to the eighth node N8, and the second electrode of the sixteenth transistor T16 is connected to the ninth node N9.

The first capacitor C1 is connected between the gate of the fourth transistor T4 and the seventh node N7, the second capacitor C2 is connected between the high potential signal VGH and the second node N2, and the third capacitor C3 is connected between the eighth node N8 and the ninth node N9.

As described above, the second transistor T2 transmits the high potential signal transmitted in the first input signal line 13 or the first output signal line 113 to the signal output terminal OUT under the control of the second node N2, and then transmits the high potential signal to the gate of the compensation transistor T03 in the pixel driving circuit 16 through the first output signal line 113.

Further, the first connection terminal 131 of the first input signal line 13 is connected to a plurality of first gate control circuits 111 arranged in the third direction N. The third connection terminal 141 of the second input signal line 14 is connected to a plurality of first gate control circuits 111 arranged in the third direction N. And the plurality of first gate control circuits 111 connected to the first input signal line 13 alternate with the plurality of first gate control circuits 111 connected to the second input signal line 14 in the third direction N.

It will be appreciated that the first gate control circuits 111 connected to the first input signal line 13 are different from the first gate control circuits 111 connected to the second input signal line 14.

Further, the second connection terminal 132 of the first input signal line 13 and the fourth connection terminal 142 of the second input signal line 14 are connected to the switching signal line 19, and the switching signal line 19 is connected to the second connection terminal 132 and the fourth connection terminal 142 at the side of the bending area 104 away from the fan-out wiring area 103.

In one or more embodiments, the switching signal line 19 extends in the first direction X, which may be the direction in which the bending area 104 is close to the fan-out wiring area 103. Note that when the third direction N is the direction in which the fan-out wiring area 103 is close to the display area 101, the first direction X is parallel to the third direction N.

The first input signal line 13 extends in the fan-out wiring area 103 in the direction inclined to the first direction X. The first input signal line 13 extends in the bending area 104 in the first direction X. And the first input signal line 13 extends in the direction inclined to the first direction X between the bending area 104 and the switching signal line 19.

The second input signal line 14 extends in the fan-out wiring area 103 in the direction inclined to the first direction X, the second input signal line 14 extends in the bending area 104 in the first direction X, and the second input signal line 14 extends in the direction inclined to the first direction X between the bending area 104 and the switching signal line 19.

It should be noted that, since the part of the display panel located in the bending area 104 needs to be bent so that the part of the display panel located on the side of the bending area 104 away from the fan-out wiring area 103 is bent to the back side, so that the flexible circuit board 20 and the circuit board 30 can be located on the back side of the display panel to reduce the width of the frame on the side of the display panel adjacent to the fan-out wiring area 103. The first input signal line 13 and the second input signal line 14 are extended in the bending area 104 in the first direction X in the embodiments of the present application, which can reduce the bending stress to which the first input signal line 13 and the second input signal line 14 are subjected. In addition, the bonding terminal(s) 12 and the first gate driving circuits 11 are not arranged in alignment, and therefore, the first input signal line 13 and the second input signal line 14 extend in the direction inclined to the first direction X in in the fan-out wiring area and in the region between the bending area 104 and the switching signal line 19 in the embodiments of the present application, so that the first input signal line 13 and the second input signal line 14 can be connected to the first gate driving circuits 11.

In one or more embodiments, the first input signal line 13 and the second input signal line 14 may be provided with through-holes in the bending area 104 to improve the bending ability of the first input signal line 13 and the second input signal line 14, and the arrangement of the through-holes is not limited in the present embodiment.

Further, the panel body 10 includes the substrate and the source-drain layer and the gate layer disposed on the substrate. The first input signal line 13, the second input signal line 14, and the switching signal line 19 may be each independently selected to be located at the source-drain layer or the gate layer.

In one or more embodiments, the source-drain layer includes the switching signal line 19. The length of the switching signal line 19 in the first direction X is greater than or equal to 100 microns, depending on the process accuracy limitations of the source-drain layer, to avoid short circuit between the first input signal lines 13, the second input signal lines 14 and the switching signal line 19 with an adjacent bonding terminal 12 during connection.

In one or more embodiments, the gate layer includes the switching signal line 19, the length of which in the first direction X is greater than or equal to 20 microns, depending on the process accuracy limitations of the gate layer, to avoid short circuit between the first input signal line 13, the second input signal line 14, and the switching signal line 19 with an adjacent bonding terminal 12 during connection.

Further, the first input signal line 13 includes a plurality of first line segments, and the plurality of first line segments are each independently located at the source-drain layer or the gate layer. That is, each first line segment may be selected to be located at the source-drain layer or the gate layer according to actual requirements. For example, the first line segment of the first input signal line 13 between the switching signal line 19 and the bending area 104 may be located at the source-drain layer, the first line segment of the first input signal line 13 within the bending area 104 may be located at the source-drain layer, and the first line segment of the first input signal line 13 within the fan-out wiring area 103 may be located at the gate layer.

The second input signal line 14 includes a plurality of second line segments, and the plurality of second line segments are each independently located at the source-drain layer or the gate layer. That is, each second line segment may be selected to be located at the source-drain layer or the gate layer according to actual requirements. For example, the second line segment of the second input signal line 14 between the switching signal line 19 and the bending area 104 may be located at the source-drain layer, the second line segment of the second input signal line 14 within the bending area 104 may be located at the source-drain layer, and the second line segment of the second input signal line 14 within the fan-out wiring area 103 may be located at the gate layer.

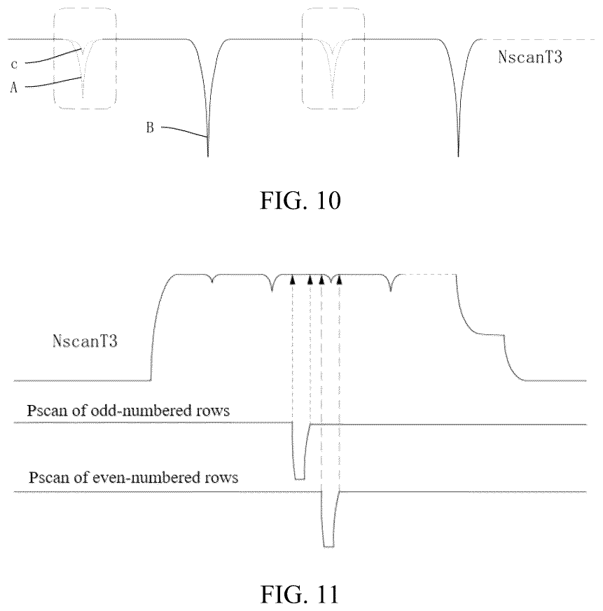

Referring to FIG. 5, FIG. 7, FIG. 9, FIG. 10, and FIG. 11, since the connection points of the first input signal line 13 to the first gate driving circuits 11 are further distant from the connection points of the second input signal line 14 to the first gate driving circuits 11 in the embodiments of the present application, the interaction between the signal transmission in the first input signal line 13 and the signal transmission in the second input signal line 14 is reduced, so that the sharp angle A appearing in the second scanning signal NscanT3 connected to the gate of the compensation transistor T03 becomes the sharp angle a, and the potential of the second scanning signal NscanT3 decreases less at the sharp angle a than at the sharp angle A. That is, the embodiments of the present application can effectively reduce the interaction between the signal transmission in the first input signal line 13 and the signal transmission in the second input signal line 14.

In one or more embodiments, a plurality of pixel driving circuits 16 are arranged in a plurality of rows and columns in the third direction N and the second direction M, where the first gate control circuits 111 connected to the first input signal line 13 may be connected to the pixel driving circuits 16 of the odd-numbered rows, and the first gate control circuits 111 connected to the second input signal line 14 may be connected to the pixel driving circuits 16 of the even-numbered rows. The period in which the first scanning signal Pscan charges to turn on one switching transistor T02 located in an odd-numbered row is offset from the period in which the sharp angle B occurs in the second scanning signal NscanT3, and the period in which the second scanning signal Pscan charges to turn on one switching transistor T02 located in an even-numbered row is offset from the period in which the sharp angle B occurs in the second scanning signal NscanT3. Since the second scanning signal NscanT3 will have a large drop fluctuation at the sharp angle B, the period in which the data writing is performed in each of the pixel driving circuits 16 in the embodiments of the present application is offset from the period in which the sharp angle B occurs in the second scanning signal NscanT3, so as to improve the stability of the pixel driving circuits 16 in the driving process.

Further, one of the period in which the first scanning signal Pscan charges to turn on the switching transistor T02 in the pixel driving circuit 16 located in the odd-numbered row and the period in which the second scanning signal Pscan charges to turn on the switching transistor T02 in the pixel driving circuit 16 located in the even-numbered row may overlap with the period in which the sharp angle occurs in the second scanning signal NscanT3, while the other overlaps with the period in which the sharp angle does not occur in the second scanning signal NscanT3.

Specifically, when the switching transistor T02 in the pixel driving circuit 16 of the preset odd-numbered rows is turned on, the compensation transistors T03 in the pixel driving circuits 16 of other odd-numbered rows other than the preset odd-number row are not charged. When the switching transistor T02 in the pixel driving circuit 16 of the preset even-numbered row is turned on, the compensation transistors T03 in the pixel driving circuits 16 of other even-numbered rows other than the preset even-numbered row are not charged.

When the switching transistor T02 located in the pixel driving circuit 16 of the preset odd-numbered row is turned on, the compensation transistors T03 located in the pixel driving circuits 16 of the even-numbered rows are charged, or when the switching transistor T02 located in the pixel driving circuit 16 of the preset even-numbered row is turned on, the compensation transistors T03 located in the pixel driving circuits 16 of the odd-numbered rows are charged.

Further, the embodiments of the present application perform brightness simulation verification on the display panels shown in FIGS. 1 and 5, and provide the comparative example in which the connection scheme shown in FIG. 1 is adopted, and an implemented example in which the connection scheme shown in FIG. 5 is adopted, and the brightness simulation data are obtained as shown in Table 1 below.

TABLE 1
brightness simulation data
[Table 1_sm_0001]

| | Comparative | Implemented |
|---|---|---|
| | Example | Example |
| size of the small sharp angle in NscanT3 | 152 | 46 |
| (mV) | | |
| Brightness of odd-numbered rows (nit) | 137.8 | 135.7 |
| Brightness of even-numbered rows (nit) | 132.3 | 134.4 |
| Difference between the odd-numbered rows | 4.07% | 0.96% |
| and the even-numbered rows | | |

As can be seen from the above Table 1, the embodiments of the present application can effectively reduce the size of the small sharp angle occurring in the NscanT3 signal, and effectively reduce the luminous brightness of pixels of odd-numbered rows and of even-numbered rows, thereby improving the display uniformity of the display panel.

As described above, the connection points of the first input signal line 13 and the second input signal line 14 are provided at one side of the bending area 104 away from the fan-out wiring area 103, so that the connection points of the first input signal line 13 and the first gate driving circuits 11 are further distant from the connection points of the second input signal line 14 and the first gate driving circuits 11, the mutual influence between the signal transmission in the first input signal line 13 and the signal transmission in the second input signal line 14 is reduced, the transmission stability of the signals in the first input signal line 13 and the second input signal line 14 can be improved, the stability of the high-potential signals output by the first gate control circuits 111 is improved, the stability of the gate signals of the compensation transistors T03 and the driving transistors T01 is improved, and the display uniformity of the display panel can be improved.

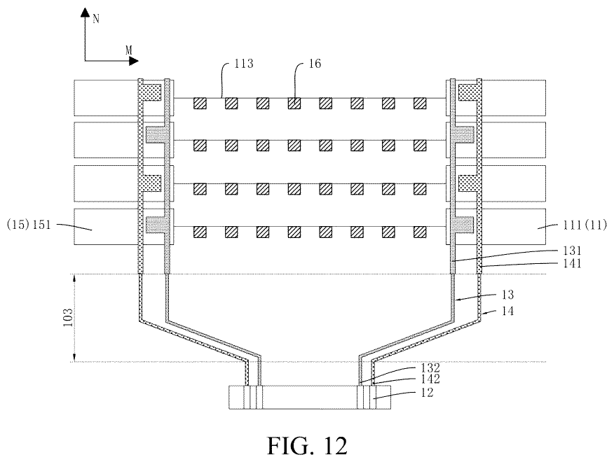

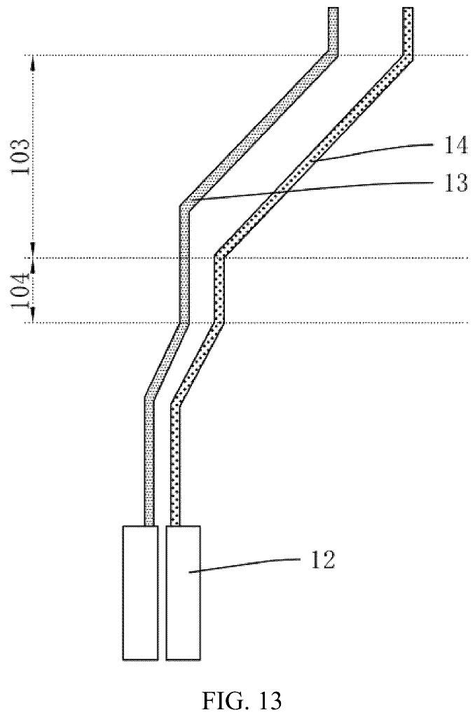

In another embodiment of the present application, referring to FIGS. 4, 12 and 13, the present embodiment differs from the embodiment shown in FIG. 5 in that the first input signal line 13 and the second input signal line 14 are connected to different bonding terminals 12.

Specifically, the display panel includes a plurality of bonding terminals 12, the second connection terminal 132 of the first input signal line 13 passes through the fan-out wiring area 103 and the bending area 104 and is connected to one bonding terminal 12, and the fourth terminal of the second input signal line 14 passes through the fan-out wiring area 103 and the bending area 104 and is connected to another bonding terminal 12.

The voltage applied by the bonding terminal 12 connected to the first input signal line 13 and the voltage applied by the bonding terminal 12 connected to the second input signal line 14 are both supplied from the driver chip 31 on the circuit board 30, and the voltages applied to the two are the same, both being same high potential signal.

As described above, the first input signal line 13 and the second input signal line 14 are respectively connected to two bonding terminals 12, so that the mutual influence of signal transmission in the first input signal line 13 and signal transmission in the second input signal line 14 is reduced, the transmission stability of signals in the first input signal line 13 and the second input signal line 14 can be improved, the stability of high-potential signals output by the first gate control circuits 111 is improved, the stability of gate signals of the compensation transistors T03 and the driving transistors T01 is improved, and the display uniformity of the display panel can be improved.

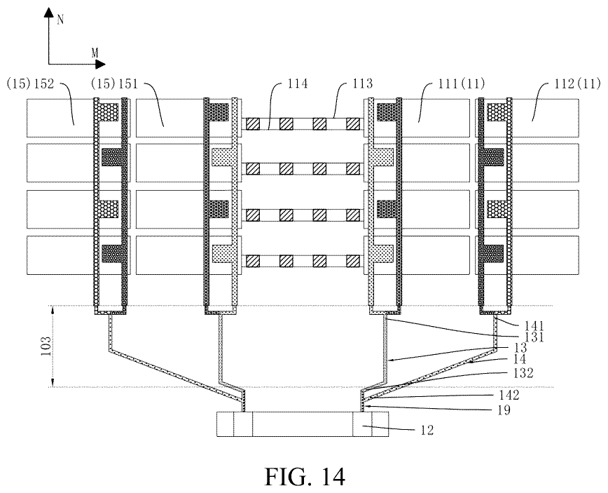

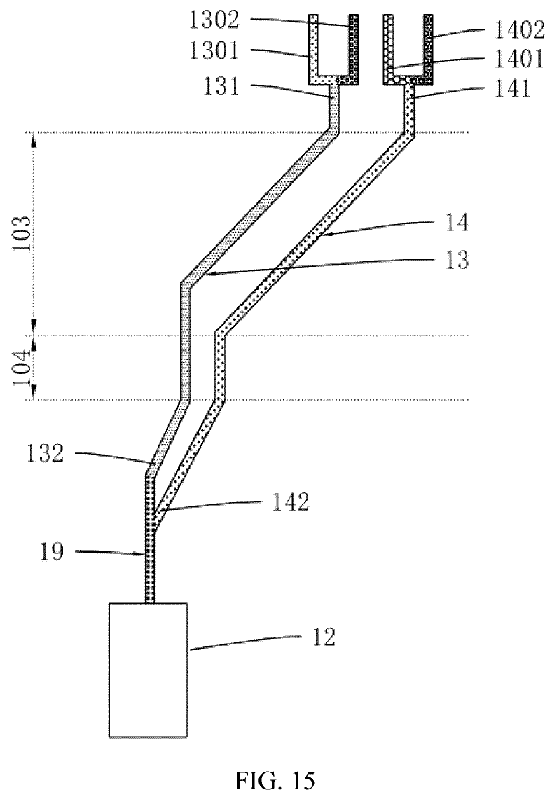

In another embodiment of the present application, referring to FIG. 4, FIG. 14, and FIG. 15, the present embodiment differs from the embodiment shown in FIG. 5 in that the first gate driving circuits 11 further include a plurality of second gate control circuits 112 disposed in the first driving circuit area 1021 and arranged in the third direction N. The panel body 10 further includes a plurality of second output signal lines 114, and a plurality of second gate control circuits 112 are located on one side of the plurality of first gate control circuits 111 that is away from or close to the display area 101.

One terminal of each of the second output signal lines 114 is connected to one of the second gate control circuits 112, and the other terminal of each of the second output signal line 114 is connected to a plurality of pixel driving circuits 16 arranged in the second direction M.

Similarly, the second gate driving circuits 15 further includes a plurality of fourth gate control circuits 152 disposed in the second driving circuit area 1022 and arranged in the third direction N, and the plurality of fourth gate control circuits 152 are located on the side of the third gate control circuits 151 that is close to or away from the display area 101. The fourth gate control circuits 152 and the second gate control circuits 112 transmit signals to the plurality of pixel driving circuits 16 arranged in the second direction M through the second output signal lines 114.

In one or more embodiments, the plurality of second gate control circuits 112 are located on the side of the plurality of first gate control circuits 111 away from the display area 101, and the plurality of fourth gate control circuits 152 are located on the side of the plurality of third gate control circuits 151 away from the display area 101.

The second output signal lines 114 are used to transmit the signals in the second gate control circuits 112 and the fourth gate control circuits 152 to the gates of the first reset transistors T04. Since parasitic capacitances exist between the gates of the first reset transistor T04 and the gates of corresponding driving transistors T01, if the gate potentials of the first reset transistors T04 are fluctuated, the gate potentials of the driving transistors T01 are also fluctuated, so that the display panel is unevenly displayed.

In the embodiments of the present application, the circuit structures of the first gate control circuits 111, the second gate control circuits 112, the third gate control circuits 151, and the fourth gate control circuits 152 may all be arranged with reference to FIG. 9, and the signals output from the first gate control circuits 111, the second gate control circuits 112, the third gate control circuits 151, and the fourth gate control circuits 152 to the pixel driving circuits 16 are the same, and may all be high potentials.

Since the signal connection mode of the fourth gate control circuits 152 is the same as the signal connection mode of the second gate control circuits 112, and the two is symmetrically arranged with respect to the display area 101, only the signal connection mode of the second gate control circuits 112 is described in the present embodiment as an example for description.

The high-potential signals in the first gate control circuits 111 and the second gate control circuits 112 may be input through the first input signal line 13 and the second input signal line 14.

Specifically, the panel body 10 further includes the first sub-line 1301 and the second sub-line 1302 connected to the first connection terminal 131. The first sub-line 1301 is connected to a plurality of first gate control circuits 111 arranged in the third direction N, the second sub-line 1302 is connected to a plurality of first gate control circuits 111 arranged in the third direction N. The plurality of first gate control circuits 111 connected to the first sub-line 1301 alternate with the plurality of first gate control circuits 111 connected to the second sub-line 1302 in the third direction N.

The panel body 10 further includes the third sub-line 1401 and the fourth sub-line 1402 connected to the third connection terminal 141. The third sub-line 1401 is connected to a plurality of second gate control circuits 112 arranged in the third direction N. The fourth sub-line 1402 is connected to a plurality of second gate control circuits 112 arranged in the third direction N. The plurality of second gate control circuits 112 connected to the third sub-line 1401 alternate with the plurality of second gate control circuits 112 connected to the fourth sub-line 1402 in the third direction N.

It will be appreciated that the first gate control circuits 111 connected to the first sub-line 1301 are different from the first gate control circuits 111 connected to the second sub-line 1302. The second gate control circuits 112 connected to the third sub-line 1401 are different from the second gate control circuits 112 connected to the fourth sub-line 1402.

Further, the second connection terminal 132 and the fourth connection terminal 142 are connected to the switching signal line 19 on the side of the bending area 104 away from the fan-out wiring area 103, so that the first input signal line 13 and the second input signal line 14 are connected to one same bonding terminal 12.

As described above, the connection points of the first input signal line 13 and the second input signal line 14 are provided at one side of the bending area 104 away from the fan-out wiring area 103, so that the connection points of the first input signal line 13 and the first gate control circuits 111 are further distant from the connection points of the second input signal line 14 and the second gate control circuits 112, the mutual influence between signal transmission in the first input signal line 13 and signal transmission in the second input signal line 14 is reduced. The transmission stability of signals in the first input signal line 13 and the second input signal line 14 can be improved, the stability of high-potential signals output by the first gate control circuit 111 is improved, the stability of gate signals of the compensation transistors T03, the first reset transistors T04 and the driving transistors T01 is improved, and the display uniformity of the display panel can be improved.

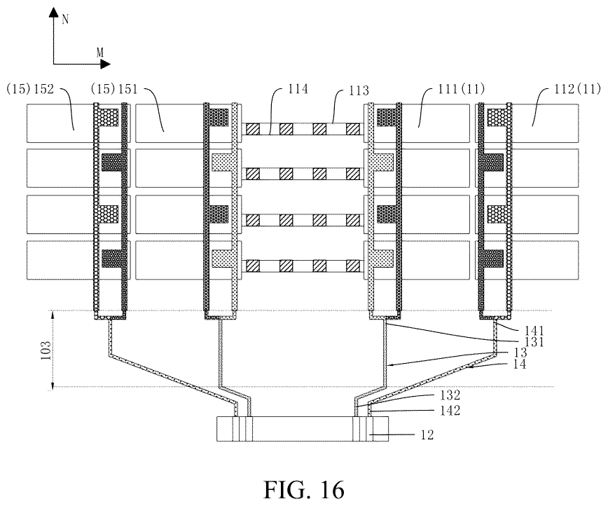

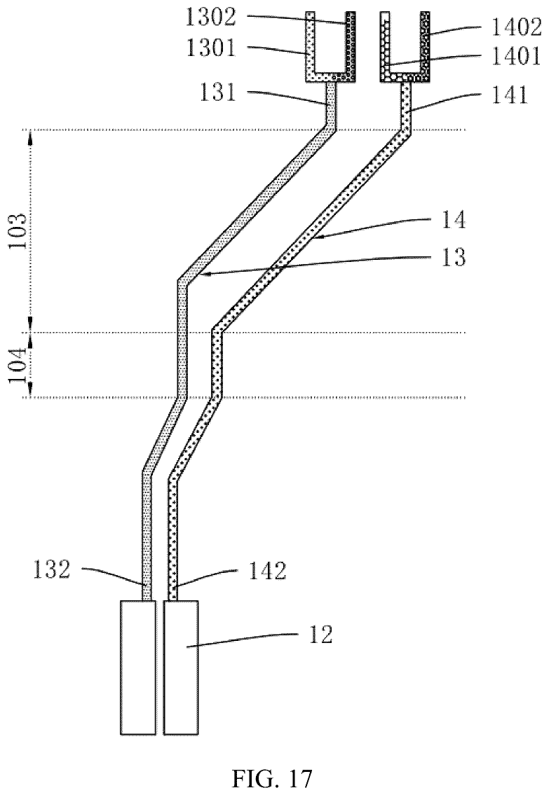

In another embodiment of the present application, referring to FIGS. 4, 16 and 17, the present embodiment differs from the embodiment shown in FIG. 14 in that the second connection terminal 132 of the first input signal line 13 passes through the fan-out wiring area 103 and the bending area 104 to be connected to one of the bonding terminals 12, and the fourth connection terminal 142 of the second input signal line 14 passes through the fan-out wiring area 103 and the bending area 104 to be connected to the other one of the bonding terminals 12.

As described above, the first input signal line 13 and the second input signal line 14 are respectively connected to two bonding terminals 12, so that the mutual influence of signal transmission in the first input signal line 13 and signal transmission in the second input signal line 14 is reduced. The transmission stability of signals in the first input signal line 13 and the second input signal line 14 can be improved, the stability of high-potential signals output by the first gate control circuits 111 is improved, the stability of gate signals of the compensation transistors T03, the first reset transistors T04 and the driving transistors T01 is improved, and the display uniformity of the display panel can be improved.

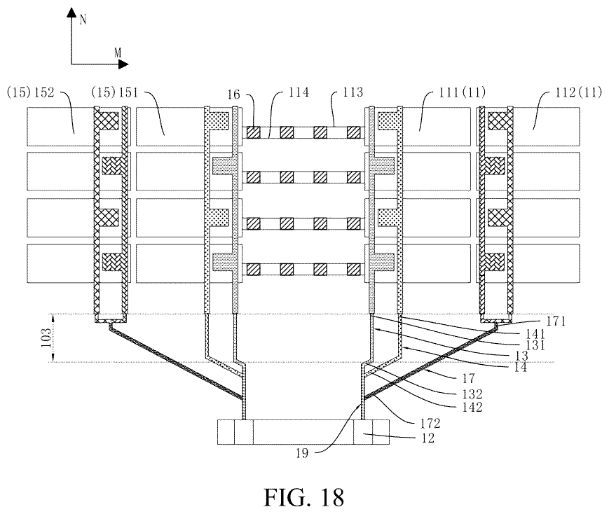

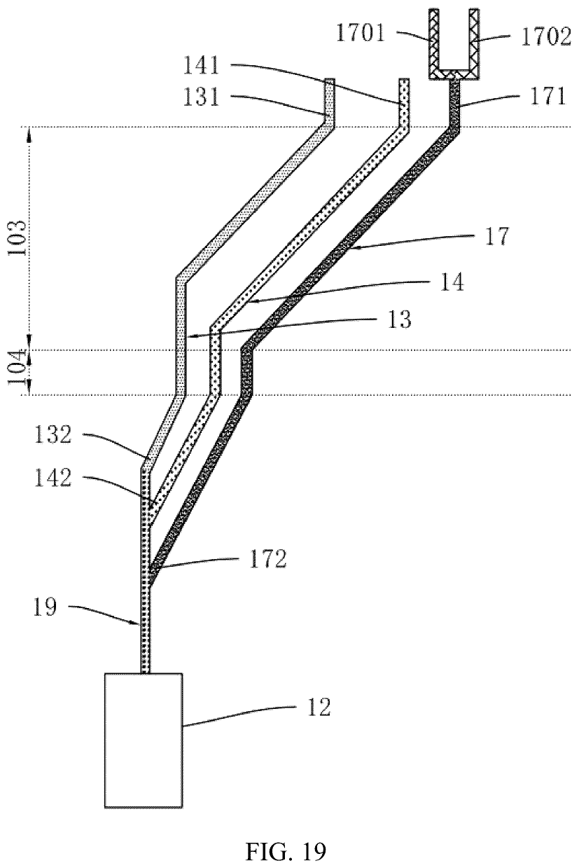

In another embodiment of the present application, referring to FIG. 4, FIG. 18 and FIG. 19, the present embodiment differs from FIG. 14 in that the panel body 10 further includes the third input signal line 17. The fifth connection terminal 171 of the third input signal line 17 is electrically connected to the second gate control circuits 112, the sixth connection terminal 172 of the third input signal line 17 passes through at least the part of the fan-out wiring area 103 and is electrically connected to the bonding terminal 12. The voltage applied by the bonding terminal 12 electrically connected to the first input signal line 13 is the same as the voltage applied by the bonding terminal 12 electrically connected to the third input signal line 17.

Specifically, the first input signal line 13 is connected to a plurality of first gate control circuits 111 arranged in the third direction N, the second input signal line 14 is connected to a plurality of first gate control circuits 111 arranged in the third direction N, and the plurality of first gate control circuits 111 connected to the first input signal line 13 alternate with the plurality of first gate control circuits 111 connected to the second input signal line 14 in the third direction N.

The fifth connection terminal 171 of the third input signal line 17 is electrically connected to the second gate control circuits 112, and the sixth connection terminal 172 of the third input signal line 17 passes through the fan-out wiring area 103 and the bending area 104 and is connected to the switching signal line 19. The second connection terminal 132 of the first input signal line 13, the fourth connection terminal 142 of the second input signal line 14, and the sixth connection terminal 172 of the third input signal line 17 are connected to the switching signal line 19 at the side of the bending area 104 away from the fan-out wiring area 103.

The panel body 10 further includes the fifth sub-line 1701 and the sixth sub-line 1702 connected to the fifth connection terminal 171. The fifth sub-line 1701 is connected to a plurality of second gate control circuits 112 arranged in the third direction N. The sixth sub-line 1702 is connected to a plurality of second gate control circuits 112 arranged in the third direction N. And the plurality of second gate control circuits 112 connected to the fifth sub-line 1701 alternate with the plurality of second gate control circuits 112 connected to the sixth sub-line 1702 in the third direction N.

It will be appreciated that the first gate control circuits 111 connected to the first input signal line 13 are different from the first gate control circuits 111 connected to the second input signal line 14. The second gate control circuits 112 connected to the fifth sub-line 1701 are different from the second gate control circuits 112 connected to the sixth sub-line 1702.

According to the embodiment of the present application, the connection points of the first input signal line 13, the second input signal line 14 and the third input signal line 17 are provided at one side of the bending area 104 away from the fan-out wiring area 103, so that the connection points of the first input signal line 13 and the first gate control circuits 111, the connection points of the second input signal line 14 and the first gate control circuits 111, and the connection points of the third input signal line 17 and the second gate control circuits 112 are made further distant from each other, which reduces mutual influence of signal transmission in the first input signal line 13, signal transmission in the second input signal line 14, and signal transmission in the third input signal line 17, thereby improving the transmission stability of signals in the first input signal line 13, the second input signal line 14, and the third input signal line 17, improving the stability of high-potential signals output by the first gate control circuits 111, and improving the stability of gate signals of the compensation transistors T03, the first reset transistors T04, and the driving transistors T01. Further, the display uniformity of the display panel can be improved.

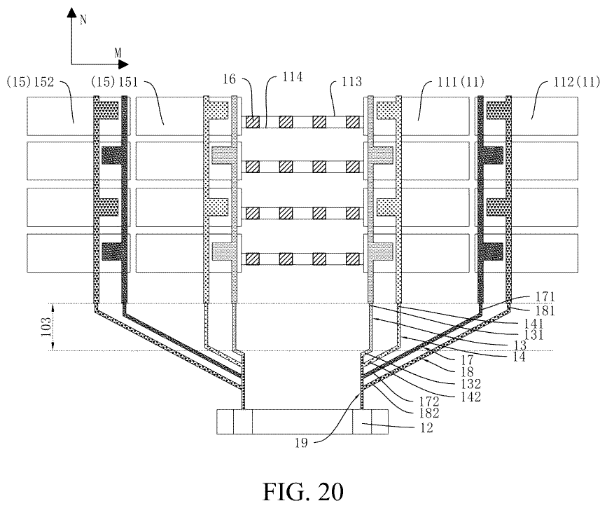

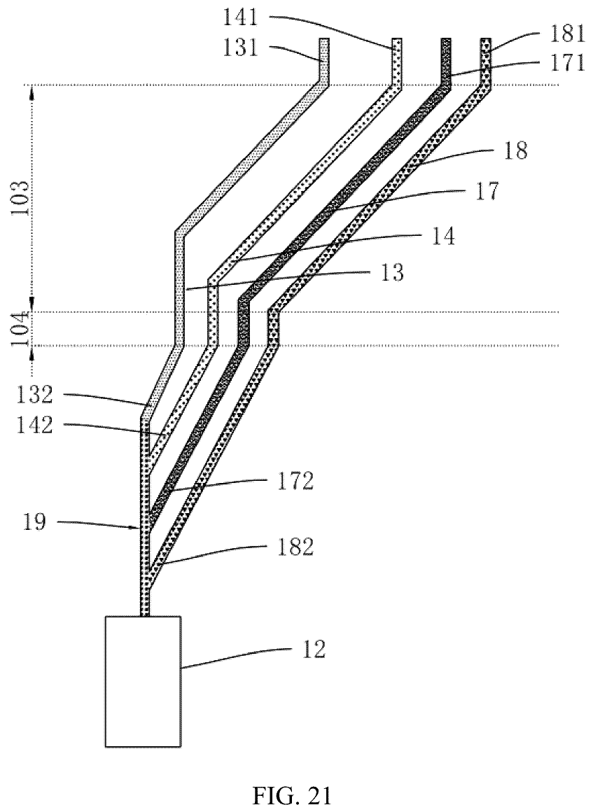

In another embodiment of the present application, referring to FIG. 4, FIG. 20 and FIG. 21, the present embodiment differs from the embodiment shown in FIG. 18 in that the panel body 10 further includes the fourth input signal line 18. The seventh connection terminal 181 of the fourth input signal line 18 is electrically connected to the second gate control circuits 112, the eighth connection terminal 182 of the fourth input signal line 18 passes through at least the part of the fan-out wiring area 103 and is electrically connected to the bonding terminal 12, and the voltage applied by the bonding terminal 12 electrically connected to the first input signal line 13 is the same as the voltage applied by the bonding terminal 12 electrically connected to the fourth input signal line 18.

Specifically, the seventh connection terminal 181 of the fourth input signal line 18 is connected to the second gate control circuits 112. The eighth connection terminal 182 of the fourth input signal line 18 passes through the fan-out wiring area 103 and the bending area 104 and is connected to the switching signal line 19. The second connection terminal 132 of the first input signal line 13, the fourth connection terminal 142 of the second input signal line 14, the sixth connection terminal 172 of the third input signal line 17, and the eighth connection terminal 182 of the fourth input signal line 18 are connected to the switching signal line 19 at the side of the bending area 104 away from the fan-out wiring area 103.

The third input signal line 17 is connected to a plurality of second gate control circuits 112 arranged in the third direction N, the fourth input signal line 18 is connected to a plurality of second gate control circuits 112 arranged in the third direction N, and the plurality of second gate control circuits 112 connected to the third input signal line 17 alternate with the plurality of second gate control circuits 112 connected to the fourth input signal line 18 in the third direction N.

It will be appreciated that the first gate control circuits 111 connected to the first input signal line 13 are different from the first gate control circuits 111 connected to the second input signal line 14. The second gate control circuits 112 connected to the third input signal line 17 are different from the second gate control circuits 112 connected to the fourth input signal line 18.

According to the embodiments of the present application, the connection points of the first input signal line 13, the second input signal line 14, the third input signal line 17, and the fourth input signal line 18 are provided at one side of the bending area 104 away from the fan-out wiring area 103, so that the connection points of the first input signal line 13 and the first gate control circuits 111, the connection points of the second input signal line 14 and the first gate control circuits 111, the connection points of the third input signal line 17 and the second gate control circuits 112, and the connection points of the fourth input signal line 18 and the second gate control circuits 112 are made further distant from each other, thereby reducing the mutual influence of the signal transmission in the first input signal line 13, the signal transmission in the second input signal line 14, the signal transmission in the third input signal line 17, and the signal transmission in the fourth input signal line 18, thereby improving the transmission stability of the signals in the first input signal line 13, the second input signal line 14, the third input signal line 17, and the fourth input signal line 18. The stability of the high-potential signal output by the first gate control circuits 111 is improved, the stability of the gate signals of the compensation transistors T03, the first reset transistors T04, and the driving transistors T01 is improved, and the display uniformity of the display panel can be improved.

In addition, one or more embodiments of the present application further provides a display device including the display panel as described in the above embodiments.

Since the display device includes the display panel described in the above embodiments, the display device has the same beneficial effect as the display panel described in the above embodiments, and details are not described herein.

In the above-mentioned embodiments, the description of each embodiment has its own emphasis, and parts not described in detail in a certain embodiment may be referred to the related description of other embodiments.

The present invention has been described in detail with reference to a display panel according to embodiments of the present application. A specific example is used to illustrate the principles and embodiments of the present application. The description of the above embodiment is merely intended to help understand the technical solution and the core idea of the present application. It will be appreciated by those of ordinary skill in the art that modifications may still be made to the technical solutions described in the foregoing embodiments, or equivalents may be made to some of the technical features therein. These modifications or equivalents do not depart the essence of the corresponding technical solutions from the scope of the technical solutions of the embodiments of the present application.

1. A display panel comprising a display area, a first driving circuit area located on a first side of the display area, and a fan-out wiring area located on a second side of the display area;
the display panel further comprises:
a panel body comprising first gate driving circuits disposed in the first driving circuit area, one or more bonding terminals disposed at a side of the fan-out wiring area away from the display area, a first input signal line, and a second input signal line;
wherein the first input signal line comprises a first connection terminal and an opposing second connection terminal, the first connection terminal is electrically connected to one or more of the first gate driving circuits, the second connection terminal is electrically connected to one of the one or more bonding terminals, and a part of the first input signal line is located in the fan-out wiring area;
the second input signal line comprises a third connection terminal and an opposing fourth connection terminal, the third connection terminal is electrically connected to one or more of the first gate driving circuits, the fourth connection terminal is electrically connected to one of the one or more bonding terminals, and a part of the second input signal line is located in the fan-out wiring area;
wherein a voltage applied by the bonding terminal electrically connected to the first input signal line is the same as a voltage applied by the bonding terminal electrically connected to the second input signal line.

2. The display panel according to claim 1, wherein the first input signal line and the second input signal line are electrically connected to same one of the one or more bonding terminals.

3. The display panel according to claim 2, wherein the panel body further comprises a switching signal line, one terminal of which is connected to the bonding terminal, and the other terminal of which is connected to the second connection terminal and the fourth connection terminal.

4. The display panel according to claim 3, wherein the second connection terminal, the fourth connection terminal, and a part of the switching signal line are all located in the fan-out wiring area.

5. The display panel according to claim 3, wherein the display panel further comprises a bending area provided on the side of the fan-out wiring area away from the display area, and the second connection terminal, the fourth connection terminal, and a part of the switching signal line are all located in the bending area.

6. The display panel according to claim 3, wherein the display panel further comprises a bending area provided on the side of the fan-out wiring area away from the display area, and the second connection terminal, the fourth connection terminal, and the switching signal line are all located on a side of the bending area away from the fan-out wiring area.

7. The display panel according to claim 6, wherein the switching signal line extends in a first direction, the first direction being a direction in which the bending area is close to the fan-out wiring area.

8. The display panel according to claim 7, wherein the first input signal line extends in a direction inclined to the first direction in the fan-out wiring area, the first input signal line extends in the first direction in the bending area, and the first input signal line extends in a direction inclined to the first direction between the bending area and the switching signal line;
the second input signal line extends in a direction inclined to the first direction in the fan-out wiring area, the second input signal line extends in the first direction in the bending area, and the second input signal line extends in a direction inclined to the first direction between the bending area and the switching signal line.

9. The display panel according to claim 7, wherein the panel body comprises a source-drain layer and a gate layer;
the source-drain layer comprises the switching signal line having a length in the first direction of greater than or equal to 100 microns;
or, the gate layer comprises the switching signal line having a length in the first direction of greater than or equal to 20 microns.

10. The display panel of claim 9, wherein the first input signal line comprises a plurality of first line segments, and each of the plurality of first line segments is independently located at the source-drain layer or the gate layer, and the second input signal line comprises a plurality of second line segments, and each of the plurality of second line segments is independently located at the source-drain layer or the gate layer.

11. The display panel according to claim 1, wherein the bonding terminal electrically connected to the first input signal line and the bonding terminal electrically connected to the second input signal line are different bonding terminals.

12. The display panel according to claim 1, wherein the panel body comprises a plurality of pixel driving circuits disposed in the display area and arranged in a second direction and a third direction, the second direction intersects the third direction, and the first gate driving circuits comprises a plurality of first gate control circuits disposed in the first driving circuit area and arranged in the third direction;
the panel body further comprises a plurality of first output signal lines, one terminal of each of the first output signal lines being connected to one of the first gate control circuits, the other terminal of each of the first output signal lines being connected to a plurality of the pixel driving circuits arranged in the second direction, the first output signal lines being used to transmit voltage signals in the first input signal line and the second input signal line to the pixel driving circuits.

13. The display panel according to claim 12, wherein the first input signal line is connected to a plurality of the first gate control circuits arranged in the third direction, the second input signal line is connected to a plurality of the first gate control circuits arranged in the third direction, and the first gate control circuits connected to the first input signal line alternate with the first gate control circuits connected to the second input signal line in the third direction.

14. The display panel according to claim 12, wherein the first gate driving circuits further comprises a plurality of second gate control circuits disposed in the first driving circuit area and arranged in the third direction, the panel body further comprises a plurality of second output signal lines, and the plurality of second gate control circuits are located on one side of the plurality of first gate control circuits away from or close to the display area;
one terminal of each of the second output signal lines is connected to one of the second gate control circuits, and the other terminal of each of the second output signal lines is connected to a plurality of the pixel driving circuits arranged in the second direction.

15. The display panel according to claim 14, wherein the panel body further comprises a first sub-line and a second sub-line connected to the first connection terminal, the first sub-line is connected to a plurality of the first gate control circuits arranged in the third direction, the second sub-line is connected to a plurality of the first gate control circuits arranged in the third direction, and the plurality of first gate control circuits connected to the first sub-line alternate with the plurality of first gate control circuits connected to the second sub-line in the third direction;
the panel body further comprises a third sub-line and a fourth sub-line connected to the third connection terminal, the third sub-line is connected to a plurality of the second gate control circuits arranged in the third direction, the fourth sub-line is connected to a plurality of the second gate control circuits arranged in the third direction, and the plurality of second gate control circuits connected to the third sub-line alternate with the plurality of second gate control circuits connected to the fourth sub-line in the third direction.

16. The display panel according to claim 14, wherein the first input signal line is connected to a plurality of the first gate control circuits arranged in the third direction, the second input signal line is connected to a plurality of the first gate control circuits arranged in the third direction, and the first gate control circuits connected to the first input signal line alternate with the first gate control circuits connected to the second input signal line;
the panel body further comprises a third input signal line, a fifth connection terminal of the third input signal line is electrically connected to the second gate control circuits, a sixth connection terminal of the third input signal line passes through at least a part of the fan-out wiring area and is electrically connected to one of the bonding terminals, and a voltage applied by the bonding terminal electrically connected to the first input signal line is the same as a voltage applied by the bonding terminal electrically connected to the third input signal line.

17. The display panel according to claim 16, wherein the panel body further comprises a fourth input signal line, a seventh connection terminal of the fourth input signal line is electrically connected to the second gate control circuits, an eighth connection terminal of the fourth input signal line passes through at least a part of the fan-out wiring area and is electrically connected to one of the bonding terminals, and a voltage applied by the bonding terminal electrically connected to the first input signal line is the same as a voltage applied by the bonding terminal electrically connected to the fourth input signal line;
the third input signal line is connected to a plurality of the second gate control circuits arranged in the third direction, the fourth input signal line is connected to a plurality of the second gate control circuits arranged in the third direction, and the plurality of the second gate control circuits connected to the third input signal line alternate with the plurality of the second gate control circuits connected to the fourth input signal line in the third direction.

18. The display panel according to claim 16, wherein the panel body further comprises a fifth sub-line and a sixth sub-line connected to the fifth connection terminal, the fifth sub-line is connected to a plurality of the second gate control circuits arranged in the third direction, the sixth sub-line is connected to a plurality of the second gate control circuits arranged in the third direction, and the plurality of second gate control circuits connected to the fifth sub-line alternate with the plurality of second gate control circuits connected to the sixth sub-line in the third direction.

19. The display panel according to claim 12, wherein each of the pixel driving circuits comprises a driving transistor and a compensation transistor, a first electrode of the driving transistor and a first electrode of the compensation transistor are both connected to a first node, a gate of the driving transistor and a second electrode of the compensation transistor are both connected to a second node, and the first output signal line is connected to a gate of the compensation transistor.

20. The display panel according to claim 19, wherein the compensation transistor is an N-type thin film transistor, and a voltage applied by the bonding terminal electrically connected to the first input signal line and a voltage applied by the bonding terminal electrically connected to the second input signal line are both high potentials.
